(19) United States
(12) Patent Application Publication
(10) Pub. No.: US 2013/0128684 A1
(43) Pub. Date: May 23, 2013

(54) REDUCED LEAKAGE BANKED WORDLINE HEADER

(71) Applicants: Stefan Buettner, Sindelfingen (DE); Thomas Froehnel, Leonberg (DE); Werner Juchmes, Boeblingen (DE); Rolf Sautter, Bondorf (DE); Victor Zyuban, Yorktown Heights, NY (US)

(72) Inventors: Stefan Buettner, Sindelfingen (DE); Thomas Froehnel, Leonberg (DE); Werner Juchmes, Boeblingen (DE); Rolf Sautter, Bondorf (DE); Victor Zyuban, Yorktown Heights, NY (US)

(73) Assignee: International Business Machines Corporation, Armonk, NY (US)

(21) Appl. No.: 13/466,973

(22) Filed: May 8, 2012

(30) Foreign Application Priority Data
May 9, 2011 (EP) 11165308.5

(51) Int. Cl. G11C 5/14; G11C 8/10

(52) U.S. Cl. CPC G11C 5/14; G11C 8/10
USPC 365/227; 365/230.06

(57) ABSTRACT

A memory array can be arranged with header devices to reduce leakage. The header devices are coupled with a decoder to receive at least a first portion of a memory address indication and are coupled to receive current from a power supply. Each of header devices is adapted to provide power from the power supply to a set of the wordline drivers corresponding to a bank indicated with the first portion of the memory address indication. Each of the logic devices is coupled to receive at least a second portion of the memory address indication from a decoder. Each of the logic devices is coupled to activate the wordline drivers coupled with those of the wordlines indicated with the second portion of the memory address indication.

### RELATED APPLICATIONS

This application claims the priority benefit of European Patent Office Application No. 11165308 filed May 9, 2011.

### BACKGROUND

Embodiments of the present inventive subject matter relate to memory circuitry, and more particularly to a reduced leakage banked wordline header.

Power consumption in conventional IT-systems is becoming more important. A part of the power consumption, e.g. in a microprocessor or in a memory array/module, refers to leakage power, which does not only increase power consumption but also causes heating of the IT-systems. In conventional server architectures, about 33% of the total core power consumption is typically based on leakage currents. The leakage power results in additional heating up of the processor, which may cause malfunction of the system, especially of the processor core. In such case, cooling of the system is required, which leads to additional power consumption. In high performance server systems, the total leakage power forms an important source of heat.

Nano-scale CMOS-technology is often used for SRAM memories, which, however, causes leakage currents and therefore accounts for leakage power. Leakage currents occurring in nano-scale transistor channels, such as 45 nm and below, are a significant contributor to the overall chip power consumption. In contrast to active power, leakage is present at any time the system is powered, even when the memory is not used. Furthermore, high performance systems require relatively high supply voltage. This has significant impact to leakage currents, such that IT-systems suffer more problems incurred from leakage as the frequency of IT-systems increases.

In a 32 kB L1 cache, about 40% of the total power consumption typically results from leakage currents. Under consideration of the overall consumption of all array structures of a state of the art microprocessor equipped with such a 32 kB L1 cache, this results in about 10% of total power consumption of the processing unit.

Several approaches have been undertaken to reduce power consumption of banked cache. A first step was to deactivate the entire SRAM cache when it is not accessed. However, as SRAM cache is frequently used, the potential for reduction of power consumption is very limited by using such an approach. In a banked cache, the SRAM memory is separated into different memory banks, which can be accessed individually for read and write access. Accordingly, access to the SRAM memory occurs even more frequently.

### SUMMARY

The inventive subject matter provides a wordline header circuit for improved leakage reduction for high performance cache systems.

Embodiments of the inventive subject matter include a memory bank comprising a plurality of wordlines adapted to activate memory cells. The electronic device comprises a plurality of wordline drivers, each of which is coupled via an output to a respective one of the plurality of wordlines, Each of the wordline drivers comprises an input to activate the wordline driver, the output to activate the respective one of the plurality of wordlines, and a power input that receives current to power the wordline driver. The electronic device comprises a decoder adapted to decode a memory access request and to generate a memory address indication from a decoded memory access request. The decoder is coupled to control delivery of power from an array supply to the power inputs of the plurality of wordline drivers based on a first part of the memory address indication, and is coupled to control selective activation of the plurality of word line drivers via the inputs thereof based on a second part of the memory address indication.

Embodiments of the inventive subject matter include a memory array comprising a plurality of banks, a plurality of wordlines coupled to each of the plurality of banks, a wordline driver coupled to each of the plurality of wordlines, a decoder, a first plurality of devices, and a second plurality of devices. The decoder is adapted to decode a memory access request and to generate a memory address indication from the memory access request. A plurality of first devices are coupled with the decoder to receive at least a first portion of the memory address indication and are coupled to receive current from a power supply. Each of the plurality of first devices is adapted to provide power from the power supply to a set of the wordline drivers corresponding to one of the plurality of banks indicated with the first portion of the memory address indication. A plurality of second devices is coupled to receive at least a second portion of the memory address indication from the decoder. Each of the plurality of second devices is coupled to activate the wordline drivers coupled with those of the plurality of wordlines indicated with the second portion of the memory address indication.

Embodiments of the inventive subject matter include a method of operating a memory array having multiple banks and a power gate for each of the banks A memory access request is decoded to generate a memory address signal. With the memory address signal, a first of the power gates is controlled to provide a current from a power supply to a set of wordline drivers of a first bank that corresponds to the first power gate. And the others of the power gates are controlled with the memory address signal to block the current from the power supply to wordline drivers of the other banks With the memory address signal, a set of logic devices is controlled to activate those of the set of wordline drivers of the first bank coupled to wordlines indicated by the memory address signal.

### BRIEF DESCRIPTION OF THE DRAWINGS

The present embodiments may be better understood, and numerous objects, features, and advantages made apparent to those skilled in the art by referencing the accompanying drawings.

FIG. 1 shows a banked SRAM cache having a power gating device for every bank that are controlled by a common acknowledge signal.

FIG. 2 shows a banked SRAM cache having a power gating device that is individually controlled for every bank according.

FIG. 3 shows a memory bank with a header control device.

FIG. 4 shows an address decoder.

FIG. 5 shows a diagram showing a comparison of overall power consumption of a conventional banked SRAM cache and a banked SRAM cache that implements the inventive subject matter.

### DESCRIPTION OF EMBODIMENT(S)

The description that follows includes exemplary systems, methods, techniques, instruction sequences and computer program products that embody techniques of the present inventive subject matter. However, it is understood that the described embodiments may be practiced without these specific details. In other instances, well-known instruction instances, protocols, structures and techniques have not been shown in detail in order not to obfuscate the description.

Instead of powering all wordline drivers of a complete memory array having multiple memory banks (e.g., 8 or 16) altogether in response to a memory access request, circuitry can selectively power the wordline drivers of the respective memory bank associated with the determined decoded address bit in response to the memory access request. In turn, all other memory banks of the memory array that do not have to be accessed in response to the memory access request, are not powered via the wordline drivers. In other words, a separate header device can be provided for each memory bank that is selectively powered by a decoder, for instance, in response to the respective memory address associated with the respective memory bank. As in banked cache systems, only one bank is usually active for a read access while another bank is usually active for a write access at the same time. With this technique, increased power saving can be obtained. For example, in an instruction cache having 16 banks whereby only two of them can be active in parallel, each bank is statistically accessed every 8 cycles. Power calculations show that additional active power, resulting from a minimum device overhead for the leakage reduction circuitry, is compensated 2.5 operating cycles after the bank was last accessed, thus forming a break-even point. This means that the power saving applies for the remaining 5.5 cycles, i.e. results in significant power savings even when operated at nearly 100% duty cycle.

The decoder provides a “double functionality.” In its first function, the decoder selectively activates the input of a respective wordline driver associated with the determined decoded address bit in response to the memory access request. In its second function, the decoder, in some embodiments simultaneously, provides power to all power inputs of all wordline drivers of the respective memory bank in response to the memory access request, but does not provide power to wordline drivers of other memory banks not relevant for performing the memory access request. In the case that one memory bank is accessed for a write operation and another memory bank is accessed for a read operation at the same time, both memory banks may be powered simultaneously via their respective wordline drivers.

Embodiments also implement an electronic device with a header control device coupled with all power inputs of all wordline drivers and with the decoder of the electronic device. The header control device is adapted to provide power to all power inputs of all wordline drivers in response to a decoded memory access request received from the decoder. In some embodiments, the header control device comprises a p-FET header device and a NOR logic device. The source of the p-FET header device is coupled with all power inputs of all wordline drivers. The drain of the p-FET header device is coupled with a voltage source. The gate of the p-FET header device is coupled with the output of the NOR logic device. The inputs of the NOR logic device are coupled with the decoder and the inputs of the NOR logic device are adapted to receive memory bank read and/or write requests from the decoder in response to the memory access request. Hence, a single NOR logic device is added as a control device in front of the p-FET header device which activates the p-FET header device in response to a memory bank read and/or write request for the respective memory bank. The NOR logic device allows for keeping active power at a minimum while achieving leakage reduction in the respective memory bank in parallel.

Embodiments can implement an electronic device with a plurality of And-Or-Invert (AOI)-logic devices. Each AOI-logic device corresponds to a wordline driver and comprises an input and an output. The output of the AOI-logic device is coupled to the input of the wordline driver and the input of the AOI-logic device is adapted to receive a memory bank read and/or write request from the decoder in response to the memory access request. In some embodiments, the wordline driver is provided as an inverter.

Embodiments can implement an electronic device as a 22-nm or smaller scaled node logic, e.g. 20-nm, 16-nm, 14-nm and/or 11-nm node logic. The electronic device is used in node logics having nano-scale transistor channels of 22-nm or below, which in turn leads to a decreased leakage when implementing the circuitry disclosed herein for such node logics.

Embodiments implement the decoder with a level shifter stage adapted to receive the memory access request and to decode the memory access request to determine the decoded address bit associated with the memory access request.

Embodiments implement a memory array with a plurality of electronic devices as described before. The decoder is adapted to provide power to all power inputs of all wordline drivers of a respective memory bank associated with the determined decoded address bit in response to the memory access request and adapted to selectively activate the input of the respective wordline driver associated with the determined decoded address bit in response to the memory access request. The decoder may also be adapted to simultaneously provide power to all power inputs of all wordline drivers of a first memory bank associated with a first electronic device for performing a write operation, and to provide power to all power inputs of all wordline drivers of a second memory bank associated with a second electronic device for performing a read operation. According to another embodiment, the memory array is adapted to operate at ≧4 GHz, at ≧5 GHz or at ≧6 GHz. In this memory array having a plurality of memory banks, only the memory bank being accessed by a respective memory access request is powered by the decoder, which in turn means that memory banks not being accessed are not powered, thus resulting in reduced overall power consumption and reduced leakage as well. Operating this memory array at four or more GHz, does not negatively impact the access times for accessing the memory cells.

Embodiments implement a SRAM cache comprising the memory array as described before and by a microprocessor comprising the SRAM cache. The SRAM caches and/or microprocessors comprising the SRAM cache having a significantly reduced leakage, while operating at nearly 100% duty cycles (e.g., in instruction caches).

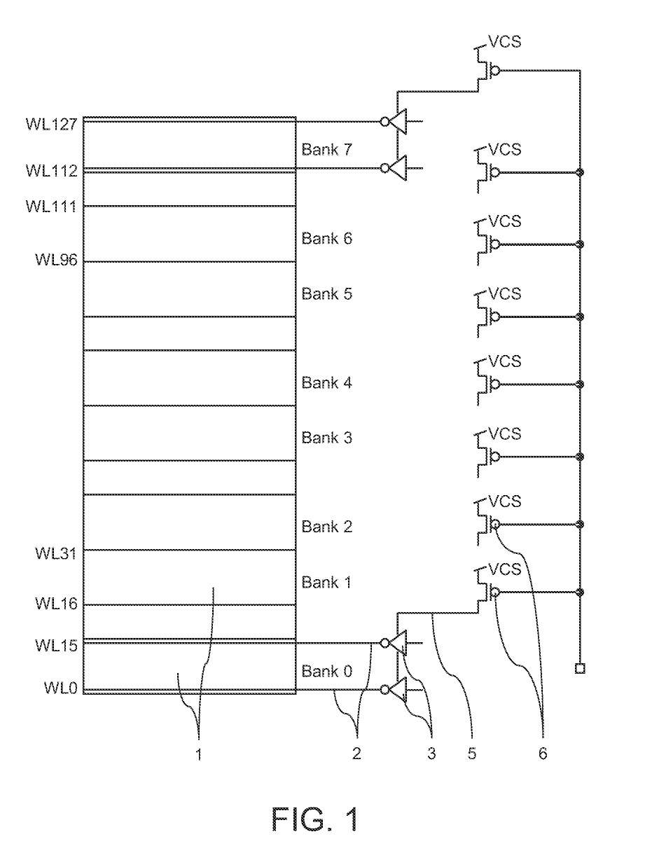

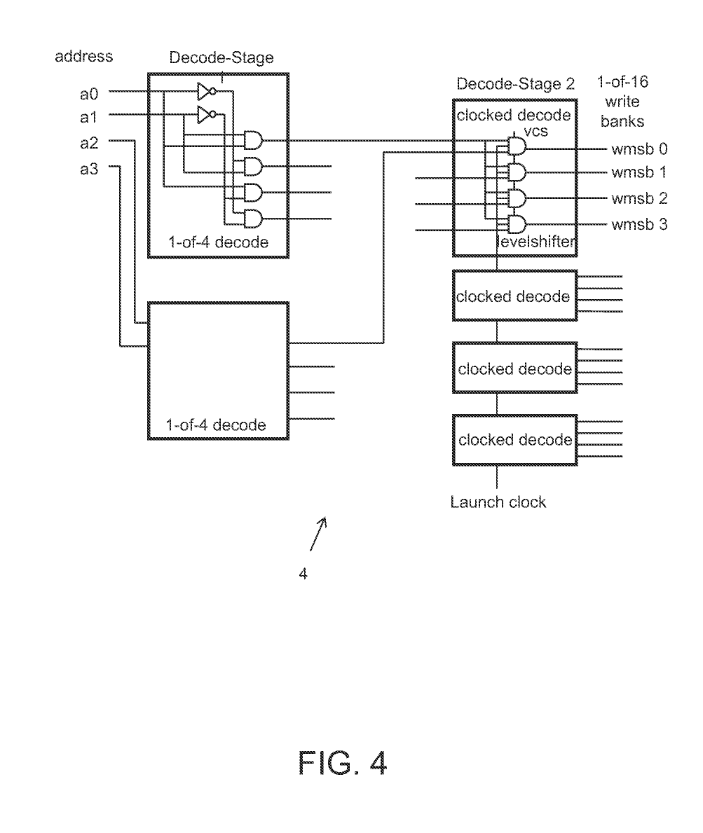

Referring now to FIG. 1, a banked SRAM cache comprising eight memory banks 1. Each memory bank 1 comprises 16 wordlines 2 for activating memory cells (not shown) provided within the memory banks 1 Each wordline is coupled to the output of a wordline driver 3. The input of the wordline driver 3 is coupled to a decoder, shown in FIG. 4. The decoder 4 is adapted for receiving a memory access request and for decoding the memory access request to determine a decoded address bit associated with the memory access request.

Power inputs 5 of the wordline drivers 3, which are adapted for receiving current to power all wordline drivers 3 associated to the memory bank 1, are coupled to a header control device 6, which is provided as a p-FET header. As can be seen further from FIG. 1, the gate inputs of all header control devices 6 are coupled in parallel such that enabling all header control devices 6 means that all wordline drivers 3 respectively all wordlines 2 are powered simultaneously and thus consume significant electrical energy when conducting a memory read and/or write access.

Such circuit as shown in FIG. 1 is used for so-called subthreshold-leakage reduction due to before described insertion of header control devices 6, also called power-gating devices, between a supply voltage and the wordline drivers 3. This means that the wordline drivers 3 are disabled if the memory array consisting out of the memory banks 1 is not accessed. The term subthreshold-leakage is thereby used for describing the drain-source leakage of a transistor, i.e. of the p-FET header device 6.

Furthermore, as can be seen from FIG. 1, a VCS voltage domain is used to power the memory banks 1 and wordline logic 2, 3 at a higher voltage compared to a standard VDD domain, which has the effect that performance and memory cell stability is improved while leakage through the wordline drivers 3 is increased. Typically, systems use wordline drivers 3 that are large inverters due to the fact that the wordline drivers 3 need to drive long cache lines within the memory banks 1.

If a memory bank 1 is accessed, the common gate input signal provided to the header control devices 6 is low and the header devices 6 are on. If no access happens, the common gate input signal to the header control devices 6 is high and all header control devices 6 are disabled, thus reducing leakage through the wordline drivers 3. In sum, such approach has the drawback that all wordline drivers 3 are enabled or disabled simultaneously, even if only a single memory bank 1 is accessed for a read and/or write operation.

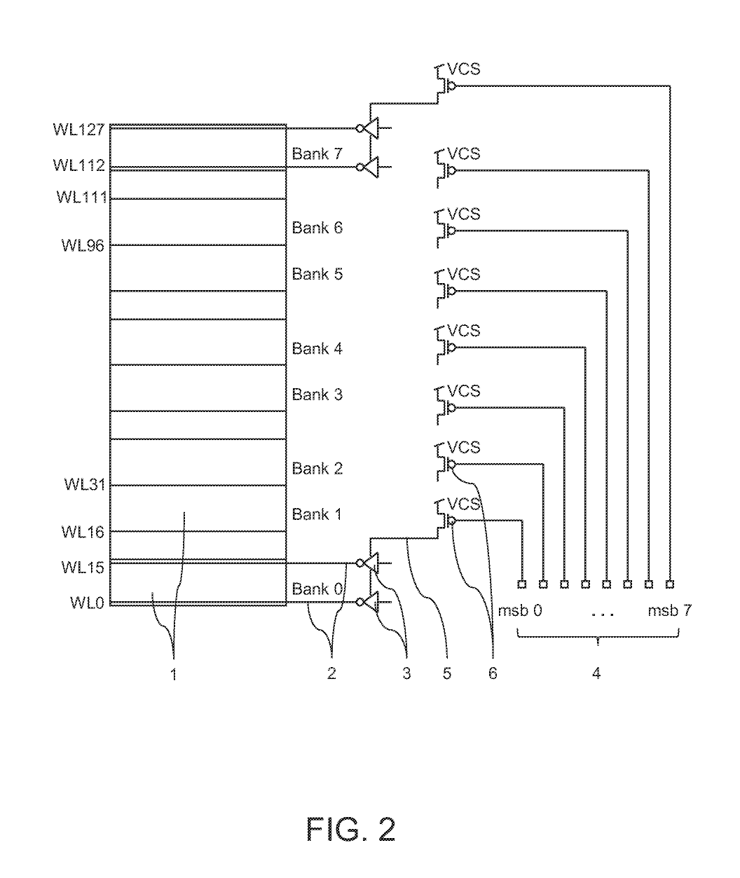

FIG. 2 shows a similar memory array as shown in FIG. 1, also having eight memory banks 1, with wordlines 2 and associated wordline drivers 3. However, in contrast to FIG. 1, the gate input of the header control devices 6 are not connected in parallel but connected individually to the decoder 4. This means that a memory access request that is processed by the decoder 4 only powers the respective header control device 6 related to the respective determined address bit determined by the decoder 4. All other memory banks 1 may not be powered via the header control devices 6 respectively via the wordline drivers 3 thus resulting in a decreased power consumption of the overall memory array and thus in a reduced leakage.

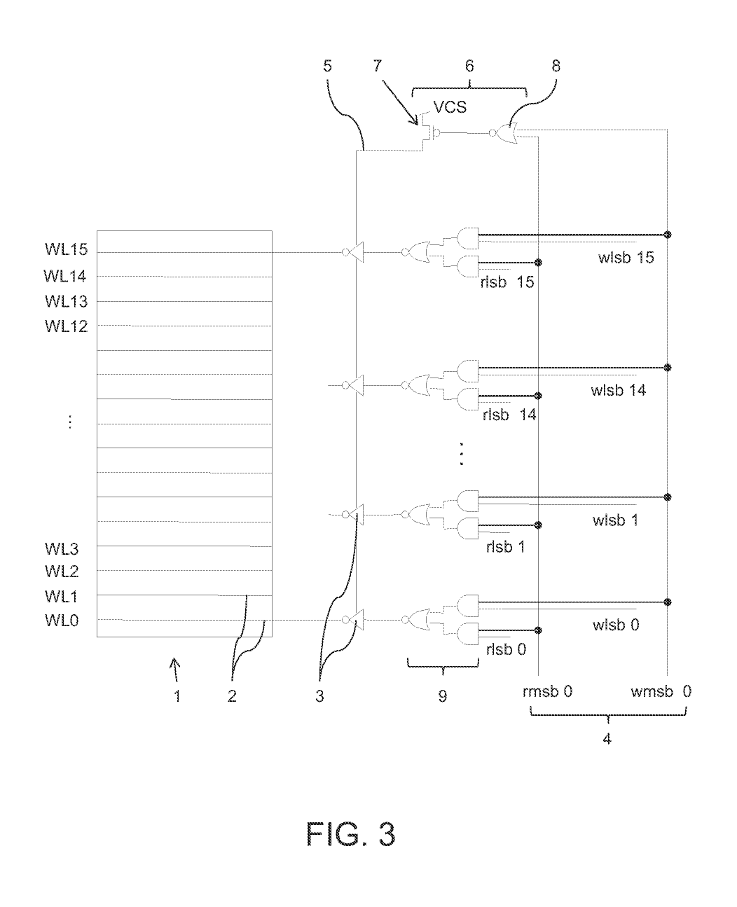

FIG. 3 shows a memory bank 1 and the respective driver circuitry 2, 3, 5, 6. As can be seen, the header control device 6 comprises a p-FET header device 7 and a NOR logic device 8, whereby the inputs of the NOR logic device 8 are coupled with the decoder 4 and are adapted for receiving memory bank 1 read and/or write requests (RMSB/WMSB) from the decoder 4 in response to the memory access request.

For enabling the inputs of the wordline drivers 3, AOI-logic devices 9 are provided that are each adapted for receiving memory bank read and/or write requests (RMSB/WMSB, RLSB, WLSB) from the decoder 4 in response to the memory access request. The decoder itself, as shown in FIG. 4 is provided as a decoder 4 which provides a “double functionality” such that the decoder 4 enables on one hand the individual read/write access to an individual wordline and on the other hand in parallel provides via the header control device 6 power for enabling the wordline drivers 3 such that the memory bank 1 can be accessed for conducting the read/write access.

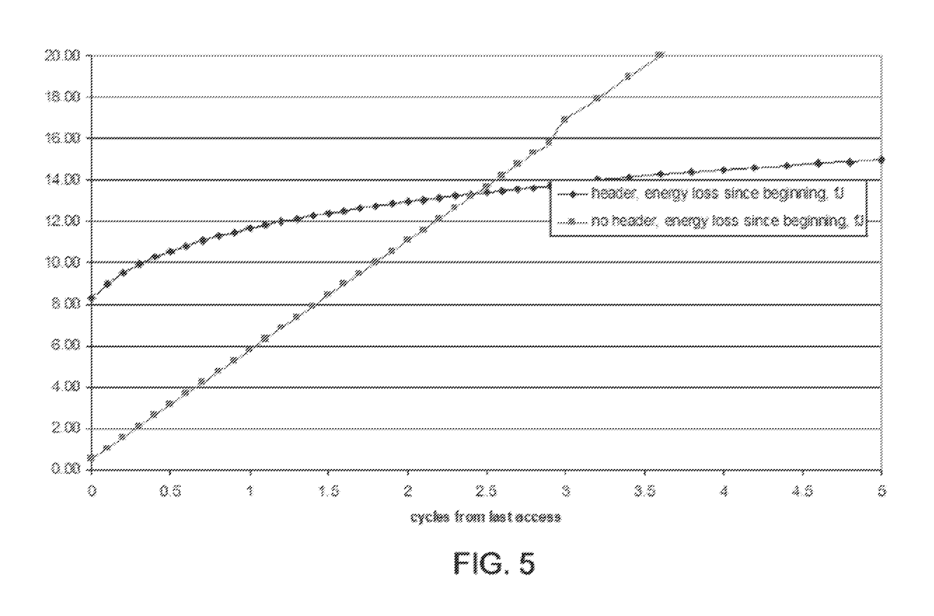

FIG. 5 shows that the solution of the inventive subject matter is advantageous over prior art systems, as already at an average access rate of a wordline driver 3 each 2.5 cycles means that the break-even point is reached. The chart refers to calculation for an instruction cache having 16 memory banks 1 whereby only two of them can be active in parallel, each memory bank 1 is statistically accessed every 8 cycles. Power calculations showed that additional active power, resulting from a minimum device overhead for the leakage reduction circuitry, is compensated 2.5 operating cycles after the memory bank 1 was last accessed, thus forming a break-even point. This means that the power saving applies for the remaining 5.5 cycles, i.e. results in significant power savings even when operated at nearly 100% duty cycle.

The flowchart and block diagrams in the Figures illustrate the architecture, functionality, and operation of possible implementations of systems, methods and computer program products according to various embodiments of the present inventive subject matter. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

As will be appreciated by one skilled in the art, aspects of the present inventive subject matter may be embodied as a system, method or computer program product. Accordingly, aspects of the present inventive subject matter may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present inventive subject matter may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present inventive subject matter may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present inventive subject matter are described with reference to flowchart illustrations and/or block diagrams of methods, apparatus (systems) and computer program products according to embodiments of the inventive subject matter. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

While the embodiments are described with reference to various implementations and exploitations, it will be understood that these embodiments are illustrative and that the scope of the inventive subject matter is not limited to them. In general, techniques for reducing leakage in memory circuits as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the inventive subject matter. In general, structures and functionality presented as separate components in the exemplary configurations may be implemented as a combined structure or component. Similarly, structures and functionality presented as a single component may be implemented as separate components. These and other variations, modifications, additions, and improvements may fall within the scope of the inventive subject matter.

What is claimed is:

1. An electronic device, comprising
a memory bank comprising a plurality of wordlines adapted to activate memory cells;
a plurality of wordline drivers, each of the plurality of wordline drivers coupled via an output to a respective one of the plurality of wordlines and comprising
an input to activate the wordline driver,
the output to activate the respective one of the plurality of wordlines, and a power input that receives current to power the wordline driver;
a decoder adapted to decode a memory access request and to generate a memory address indication from a decoded memory access request, the decoder coupled to control delivery of power from an array supply to the power inputs of the plurality of wordline drivers based on a first part of the memory address indication and coupled to control selective activation of the plurality of word line drivers via the inputs thereof based on a second part of the memory address indication.

2. The electronic device according to claim 1 further comprising a header control device coupled to receive the first part of the memory address indication from the decoder and coupled to provide power to the power inputs of the plurality of wordline drivers in accordance with the first part of memory address indication.

3. The electronic device according to claim 2, wherein the header control device comprises a p-FET header device and a NOR logic device, the source of the p-FET header device is coupled with the power inputs of the wordline drivers, the drain of the p-FET header device is coupled with the array supply, the gate of the p-FET header device is coupled with the output of the NOR logic device, the inputs of the NOR logic device are coupled to receive the first part of the memory address indication from the decoder.

4. The electronic device according to claim 1 further comprising a plurality of And-Or-Inverter logic devices coupled between the plurality of wordline drivers and the decoder, each of the plurality of And-Or-Inverter logic devices comprising an output coupled to the input of a respective one of the plurality of wordline drivers and an input coupled to receive the second part of the memory address indication from the decoder.

5. The electronic device according to claim 1, wherein the wordline driver comprises an inverter.

6. The electronic device according to claim 1, wherein the electronic device is a 22-nm or smaller scaled node logic.

7. The electronic device according to claim 1, wherein the decoder comprises a level shifter stage adapted to receive the memory access request, wherein the decoder adapted to generate the memory address indication from the decoded memory access request comprises the decoder adapted to determine address bits of the memory access request.

8. The electronic device of claim 1, wherein the first part of the memory address indication indicates the memory buffer and the second part of the memory address indication indicates one or more of the plurality of wordlines corresponding to the memory access request.

9. A memory array comprising:
a plurality of banks;
each of the plurality of banks coupled with a plurality of wordlines;
a wordline driver coupled to each of the plurality of wordlines;
a decoder adapted to decode a memory access request and to generate a memory address indication from the memory access request;
a plurality of first devices coupled with the decoder to receive at least a first portion of the memory address indication and coupled to receive current from a power supply, each of the plurality of first devices adapted to provide power from the power supply to a set of the wordline drivers corresponding to one of the plurality of banks indicated with the first portion of the memory address indication; and
a plurality of second devices coupled to receive at least a second portion of the memory address indication from the decoder, each of the plurality of second devices coupled to activate the wordline drivers coupled with those of the plurality of wordlines indicated with the second portion of the memory address indication

10. The memory array of claim 9, wherein the power supply comprises an array supply.

11. The memory array of claim 9, wherein each of the plurality of first devices comprises a p-FET header device and a NOR logic device, a source of the p-FET header device is coupled to provide power to the wordline drivers of a respective one of plurality of banks, a drain of the p-FET header device is coupled to receive power from the power supply, a gate of the p-FET header device is coupled with an output of the NOR logic device, inputs of the NOR logic device are coupled to receive the first portion of the memory address indication from the decoder.

12. The memory array according to claim 9, wherein each of the plurality of second devices comprises an And-Or-Inverter logic device, the And-Or-Inverter logic device comprising an output coupled to a respective one of the plurality of wordline drivers and an input coupled to receive the second portion of the memory address indication from the decoder.

13. The memory array according to claim 9, wherein the memory array operates at any one of ≧4 GHz, ≧5 GHz, and ≧6 GHz.

14. The memory array of claim 9, wherein the decoder comprises a level shifter.

15. A method of operating a memory array having multiple banks and a power gate for each of the banks, the method comprising:
decoding a memory access request to generate a memory address signal;
controlling, with the memory address signal, a first of the power gates to provide a current from a power supply to a set of wordline drivers of a first bank that corresponds to the first power gate, and the others of the power gates to block the current from the power supply to wordline drivers of the other banks; and
controlling, with the memory address signal, a set of logic devices to activate those of the set of wordline drivers of the first bank coupled to wordlines indicated by the memory address signal.

16. The method of claim 15, wherein the power supply comprises an array supply.

17. The method of claim 15, wherein said decoding the memory access request comprises determining memory address bits of the memory access and converting the memory access request into the array supply voltage domain.

18. The method of claim 15 further comprising a decoder receiving the memory access request.

19. The method of claim 15, wherein said controlling, with the memory address signal, the first power gate and the others of the power gates comprises supplying a first part of a memory address encoded in the memory address signal to the power gates, wherein the first part of the memory address corresponds to the first bank.

20. The method of claim 19, wherein said controlling, with the memory address signal, the set of logic devices comprises supplying a second part of the memory address encoded in the memory address signal to the set of logic devices, wherein the second part of the memory address indicates a set of wordlines.
